(19) United States
(12) Patent Application Publication
(10) Pub. No.: US 2026/0360395 A1
(43) Pub. Date: Nov. 12, 2026

(54) DEVICE WITH FLY METAL LINE AND CONNECTION STRUCTURE

(71) Applicant: Taiwan Semiconductor Manufacturing Co., Ltd., Hsinchu (TW)

(72) Inventors: Yung-Ting Chang, New Taipei (TW); Feng-Ming Chang, Zhubei (TW)

(21) Appl. No.: 19/357,464

(22) Filed: Oct. 14, 2025

Related U.S. Application Data
(60) Provisional application No. 63/829,029, filed on Jun. 24, 2025.
(60) Provisional application No. 63/803,313, filed on May 9, 2025.

(51) Int. Cl. G11C 5/06; H10B 10/00; H10W 20/00; H10W 20/40; H10W 20/41; H10W 20/42; H10W 20/43

(52) U.S. Cl. CPC G11C 5/063; H10B 10/12; H10W 20/0698; H10W 20/422; H10W 20/43; H10W 20/435; H10W 20/498

(57) ABSTRACT

An embodiment is a device including a memory array having a first array segment and a second array segment arranged along a first direction, a first wordline segment extending through the first array segment in the first direction, and a second wordline segment extending through the second array segment in the first direction. The second wordline segment is separated from the first wordline segment by a cut region. The memory device further comprises a fly wordline extending over the first array segment and the second array segment in a metal layer above the first wordline segment and the second wordline segment, and a connection structure electrically coupling the fly wordline to the second wordline segment. The connection structure includes a conductive line island in an intermediate metal layer between the fly wordline and the second wordline segment, wherein the intermediate metal layer comprises conductive line jogs.

### PRIORITY CLAIM AND CROSS-REFERENCE

This application claims the benefit of U.S. Provisional Application No. 63/803,313, filed on May 9, 2025, and U.S. Provisional Application No. 63/829,029, filed Jun. 24, 2025 which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory system with a memory controller and memory array, according to some embodiments.

FIG. 2 illustrates a circuit diagram of a memory cell with cross-coupled inverters and pass gate transistors, according to some embodiments.

FIGS. 3 and 4 illustrate a memory array structure with segmented wordlines and a fly wordline extending across array segments, according to some embodiments.

FIG. 5 illustrates a circuit layout showing a conductive interconnect structure with conductive line islands, according to some embodiments.

FIG. 6 illustrates a cross-sectional view of a semiconductor device structure with multiple metal layers and via connections, according to some embodiments.

FIGS. 7A, 7B, 7C, and 7D illustrate circuit layouts showing memory regions and interconnect structures at various metallization layers, according to some embodiments.

FIG. 8 illustrates a block diagram of a memory device with multiple fly wordlines and array segments, according to some embodiments.

FIG. 9 illustrates a system diagram of a memory device with a second fly wordline in a higher metallization layer, according to some embodiments.

FIGS. 10A, 10B, 10C, 10D, 10E, and 10F illustrate circuit layouts showing memory regions and interconnect structures at various metallization layers, according to some embodiments.

FIG. 11 illustrates a flowchart for a method of routing signals in a memory device, according to some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Memory devices such as static random-access memory (SRAM) face challenges related to signal transmission across large memory arrays. As memory arrays increase in size to accommodate higher storage densities, wordlines formed in lower metal layers (such as M1) experience increased electrical resistance when extending from periphery circuits to far-end memory cells. This high wordline resistance causes significant voltage drops and bounce at far-end locations, leading to timing delays and compromised signal integrity that affect reliable memory operation.

Memory array designs rely on wordlines formed in lower metal layers, such as the first metal layer, to connect wordline drivers to memory cells throughout the array. However, lower metal layers typically have higher sheet resistance compared to upper metal layers, which exacerbates the resistance problem in long wordlines. When a wordline signal travels from the periphery of the memory array to memory cells at the far end, the accumulated resistance can cause the signal voltage to drop below acceptable levels. This voltage degradation can result in insufficient gate drive for pass transistors in the memory cells, leading to read and write failures or reduced operating margins.

Some embodiments address these challenges through the use of fly wordlines implemented in higher metal layers that have lower sheet resistance than the lower metal layers used for other wordlines. A fly wordline can extend over multiple array segments and provide an alternative signal path that bypasses the high-resistance portions of the other wordline structure. The fly wordline can be positioned in a metal layer such as the fifth metal layer or seventh metal layer, which typically exhibits lower resistance per unit length compared to the first metal layer where wordlines are typically formed.

The disclosed embodiments address the far-end wordline resistance problem through an interconnect architecture featuring strategically positioned conductive islands within intermediate metal layers, particularly utilizing M3 jog designs. These conductive islands, isolated from surrounding conductive line jogs in the same metal layer, create dedicated vertical signal paths that enable fly wordlines in higher metal layers (such as M5 or M7) to deliver signals to far-end devices with substantially reduced resistance and IR drop.

The connection between the fly wordline and the segmented wordlines utilizes a multi-layer interconnect structure that includes conductive islands formed in intermediate metal layers. These conductive islands serve as links for the signal path, allowing the wordline signal to transition from the higher metal layer of the fly wordline down to the lower metal layer of the wordline segments. The intermediate metal layers may include conductive line jogs that provide routing flexibility while maintaining electrical isolation between different signal paths.

The conductive island structure enables efficient signal routing by providing isolated conductive regions within metal layers that would otherwise carry other signals or remain unused. By incorporating conductive islands in intermediate metal layers such as the third metal layer, the interconnect structure can route wordline signals vertically through the metal stack while avoiding interference with other circuit elements. This approach reduces the overall resistance of the signal path from the wordline driver to distant memory cells, thereby improving signal integrity and enabling reliable operation of large memory arrays.

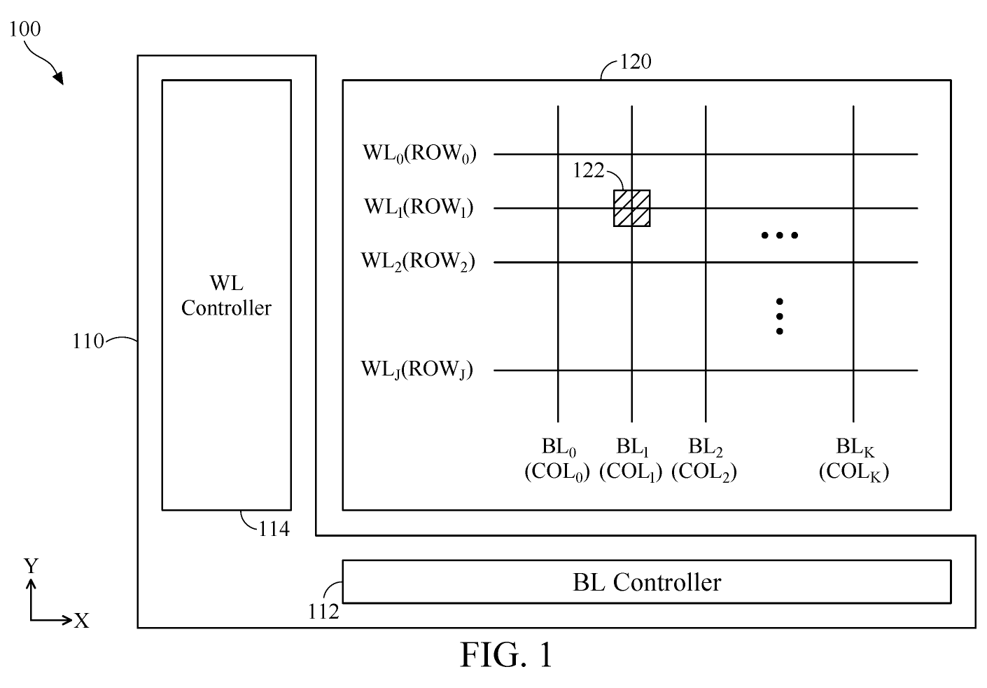

FIG. 1 illustrates a memory device 100 that implements an advanced architecture for SRAM array optimization. The memory device 100 provides a comprehensive solution for addressing the electrical resistance and capacitance challenges that arise when expanding memory arrays to achieve higher density storage. The memory device 100 may incorporate both frontside and backside metallization schemes to enable larger array configurations while maintaining acceptable performance characteristics.

The memory device 100 includes a memory controller 110 that manages the overall operation and access control for the memory storage system. The memory controller 110 coordinates the various control signals and data pathways within the memory device 100 to enable proper reading and writing operations. The memory controller 110 serves as the central coordination point for managing access to the stored data and controlling the timing of memory operations.

The memory controller 110 comprises a bitline controller 112 that manages the bitline signals throughout the memory device 100. The bitline controller 112 controls the electrical signals that travel along the bitlines to access individual memory locations during read and write operations. The bitline controller 112 may be positioned to provide optimal signal routing and control for the bitline network within the memory device 100.

The memory controller 110 also includes a wordline controller 114 that manages the wordline signals for memory cell selection. The wordline controller 114 controls the activation of specific rows of memory cells by managing the wordline signals that enable or disable access to particular memory cells. The wordline controller 114 may be arranged in an orthogonal configuration relative to the bitline controller 112 to provide comprehensive two-dimensional addressing capability for the memory array.

The memory device 100 contains a memory array 120 that houses the actual memory storage elements. The memory array 120 may be positioned between the wordline controller 114 and the bitline controller 112 to enable coordinated access control from both controllers. The memory array 120 comprises multiple array segments, with each array segment containing memory cells arranged in rows and columns. In some cases, the memory array 120 comprises at least four array segments to enable the segmented bitline optimization approach. The memory array 120 includes a first array segment comprising first memory cells, a second array segment comprising second memory cells, and a third array segment comprising third memory cells, with additional segments providing further expansion capability.

The memory array 120 contains multiple memory cells 122 that serve as the individual storage elements within the memory device 100. Each memory cell 122 may be implemented as an SRAM cell capable of storing a single bit of data. The memory cells 122 may be arranged in a regular grid pattern with rows and columns to enable systematic addressing and access through the coordinated operation of the bitline controller 112 and wordline controller 114.

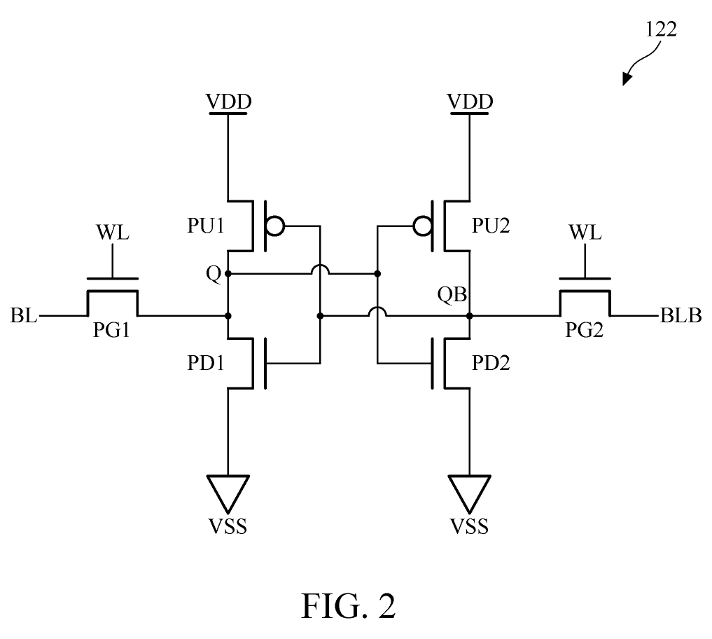

FIG. 2 illustrates the detailed circuit structure of an individual memory cell 122 that forms the basic storage element within the memory array 120. The memory cell 122 implements a six-transistor (6T) SRAM configuration that provides stable data storage through a cross-coupled inverter arrangement combined with controlled access mechanisms. The circuit structure enables reliable data retention while allowing selective access for read and write operations through the coordinated control of wordline and bitline signals. The memory cell 122 may be replicated throughout the memory array 120 to create a comprehensive storage system with uniform electrical characteristics and predictable performance across all storage locations.

The memory cell 122 includes a pass gate transistor PG1 that provides controlled access to one side of the storage element. The pass gate transistor PG1 may be connected between a bitline (BL) and an internal storage node of the memory cell 122. The pass gate transistor PG1 receives control signals from a wordline (WL) that determines when the memory cell 122 may be accessed for read or write operations. When the wordline signal activates the pass gate transistor PG1, the bitline becomes electrically connected to the internal storage node, enabling data transfer between the external bitline network and the internal storage mechanism of the memory cell 122.

The circuit structure also incorporates a complementary pass gate transistor PG2 that provides access control for the opposite side of the storage element. The complementary pass gate transistor PG2 may be connected between a complementary bitline (BLB) and a second internal storage node within the memory cell 122. The complementary pass gate transistor PG2 also receives control signals from the same wordline (WL) that controls the pass gate transistor PG1, ensuring that both access paths are activated simultaneously during memory operations. This dual access configuration enables differential signaling and improved noise immunity during data transfer operations.

The storage mechanism within the memory cell 122 includes a pull up transistor PU1 that forms part of the first inverter in the cross-coupled configuration. The pull up transistor PU1 may be connected between a power supply voltage (VDD) and one of the internal storage nodes, providing the high-level drive capability for maintaining stored data. The pull up transistor PU1 works in conjunction with other transistors to create a stable storage state that can maintain data indefinitely as long as power remains applied to the memory cell 122. The pull up transistor PU1 may be implemented as a PMOS transistor to provide effective high-level drive characteristics.

The first inverter configuration is completed by a pull down transistor PD1 that provides the low-level drive capability for the storage node. The pull down transistor PD1 may be connected between the same internal storage node and a ground reference voltage (VSS), creating a complete inverter structure when combined with the pull up transistor PU1. The pull down transistor PD1 may be implemented as an NMOS transistor to provide effective low-level drive characteristics. The combination of the pull up transistor PU1 and pull down transistor PD1 creates a stable inverter that can drive the internal storage node to either a high or low logic state based on the input conditions.

The cross-coupled storage configuration includes a complementary pull up transistor PU2 that forms part of the second inverter in the memory cell 122. The complementary pull up transistor PU2 may be connected between the power supply voltage (VDD) and the second internal storage node, providing high-level drive capability for the complementary side of the storage element. The complementary pull up transistor PU2 works in conjunction with the complementary pull down transistor to create the second half of the cross-coupled inverter pair. The gate of the complementary pull up transistor PU2 may be connected to the first internal storage node, creating the cross-coupling connection that enables stable data storage.

The second inverter is completed by a complementary pull down transistor PD2 that provides low-level drive capability for the second internal storage node. The complementary pull down transistor PD2 may be connected between the second internal storage node and the ground reference voltage (VSS), forming a complete inverter structure when combined with the complementary pull up transistor PU2. The gate of the complementary pull down transistor PD2 may also be connected to the first internal storage node, completing the cross-coupling arrangement that creates the bistable storage characteristic of the memory cell 122. This cross-coupled configuration ensures that the two internal storage nodes maintain complementary logic states, providing stable data storage with strong noise immunity and data retention capabilities.

The transistors within the memory cell 122 may be implemented using various semiconductor device technologies to achieve the desired electrical characteristics and performance requirements. In some embodiments, the transistors may be implemented as planar metal-oxide-semiconductor field-effect transistors (MOSFETs) that utilize conventional planar gate structures formed on the substrate surface. The planar MOSFET configuration may provide established fabrication processes and predictable electrical characteristics for the memory cell implementation.

In some cases, the transistors may be implemented as fin field-effect transistors (FinFETs) that utilize three-dimensional fin structures to provide improved electrostatic control and reduced leakage currents. The FinFET configuration may offer enhanced performance characteristics compared to planar devices, particularly in advanced technology nodes where improved short-channel control becomes beneficial for memory cell operation.

In some aspects, the transistors may be implemented as gate-all-around field-effect transistors (GAA FETs) that provide electrostatic control through gate structures that completely surround the channel region. The GAA FET configuration may offer improved short-channel control and reduced variability compared to other transistor structures, potentially enabling more consistent performance across the memory array 120. The gate-all-around structure may provide enhanced immunity to process variations and improved scalability for advanced memory implementations.

The transistor implementation may also utilize various other advanced transistor structures that provide optimized characteristics for SRAM applications. These alternative structures may include nanowire transistors, nanosheet transistors, or other device architectures that offer improved electrostatic control, reduced leakage, or enhanced performance characteristics. The selection of the specific transistor technology may depend on the performance requirements, power constraints, and manufacturing considerations for the particular memory device 100 implementation.

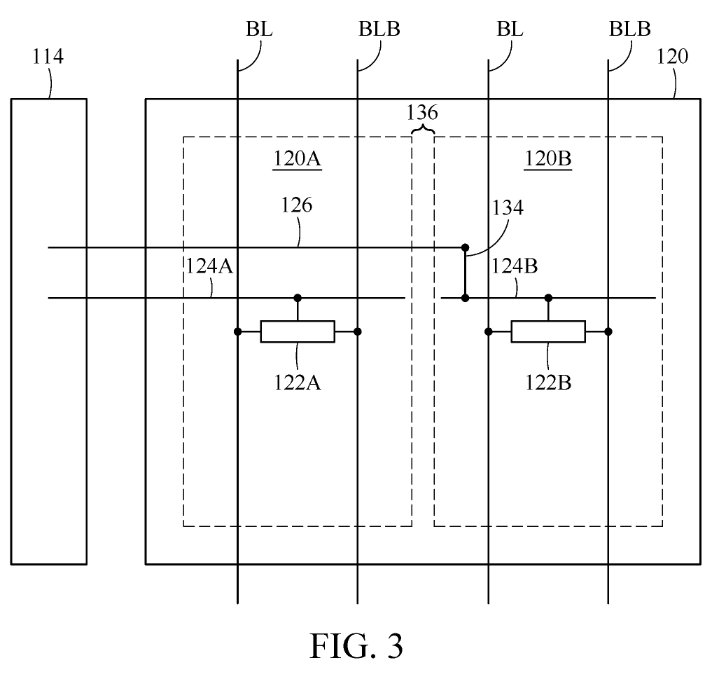

FIG. 3 illustrates a segmented memory array architecture that addresses signal integrity challenges in large memory arrays. The segmented approach divides the memory array 120 into discrete sections with independent control while maintaining coordinated operation through advanced interconnect structures. This configuration enables improved signal distribution and reduced electrical resistance compared to single-segment arrays, providing enhanced flexibility for memory array layout optimization while ensuring reliable access to all memory storage locations.

The memory array 120 includes a first array segment 120A positioned adjacent to the wordline controller 114 for direct signal routing from control circuitry. This segment contains a first segment bitcell 122A implemented using the same circuit structure as the memory cell 122, providing consistent electrical characteristics across the segmented array structure.

The second array segment 120B provides additional memory storage capacity at a greater distance from the wordline controller 114, creating potential signal distribution challenges with other routing approaches. This segment contains a second segment bitcell 122B that utilizes the same fundamental circuit design while being positioned at a location that would traditionally experience signal degradation due to wordline resistance.

A first wordline segment 124A extends through the first array segment 120A in a lower metal layer, such as the first metal layer, connecting directly to the wordline controller 114 for memory access operations. The segmented architecture includes a second wordline segment 124B extending through the second array segment 120B in the same lower metal layer, but electrically separated from the first wordline segment 124A to enable independent control and signal routing optimization.

A cut region 136 separates the first wordline segment 124A from the second wordline segment 124B by removing or omitting wordline material in the lower metal layer, creating electrical isolation that prevents direct connection through the lower wordline path. This separation enables independent signal routing to each segment while providing the physical space needed for advanced interconnect approaches.

The architecture incorporates a first fly wordline 126 that provides an alternative signal path by extending over both array segments in a higher metal layer, such as the fifth metal layer, which exhibits lower sheet resistance than lower wordline layers. This fly wordline enables signal transmission across the segmented array structure while bypassing the high-resistance path of continuous wordline implementations.

A connection structure 134 provides electrical coupling between the first fly wordline 126 and the second wordline segment 124B through multiple metal layers and via connections, creating a vertical interconnect path from the higher metal layer to the lower metal layer. This structure enables efficient signal routing while maintaining electrical isolation from other circuit elements, positioned optimally within the second array segment 120B to provide effective signal distribution to memory cells in this remote section.

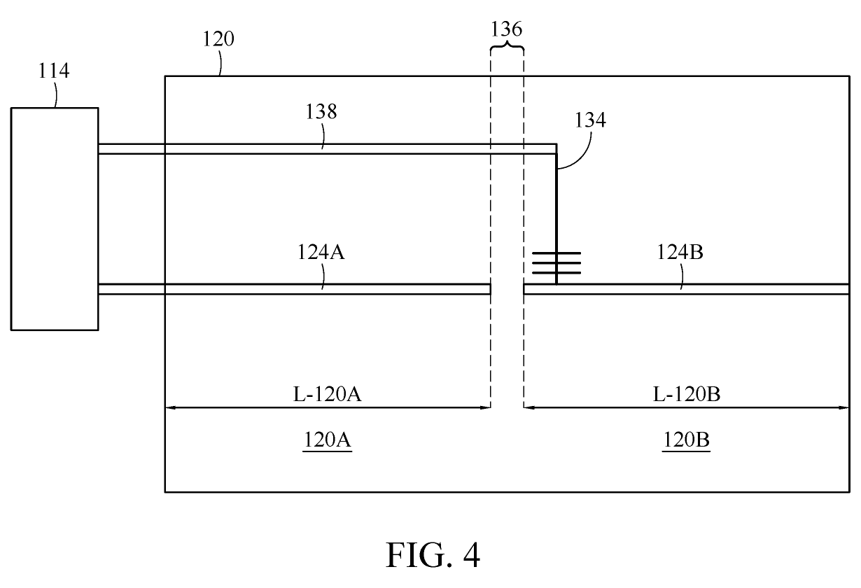

FIG. 4 illustrates a memory device configuration that demonstrates the flexible array segment sizing capabilities within the segmented memory architecture. The memory device provides configurable segment lengths that may be optimized based on specific performance requirements, layout constraints, and electrical characteristics. The segmented approach enables independent sizing of different array portions while maintaining coordinated signal routing through the fly wordline structure.

The first array segment 120A incorporates a first segment length L-120A that defines the physical extent of this array section along the wordline direction. The first segment length L-120A may be determined based on factors such as the desired memory capacity within this segment, the electrical characteristics of the wordline routing, and the layout efficiency considerations for the overall memory device. The first segment length L-120A establishes the distance over which the first wordline segment 124A extends to provide access control for the first segment bitcell 122A and other memory cells within this array section.

The second array segment 120B includes a second segment length L-120B that determines the physical dimensions of this remote array section. The second segment length L-120B may be independently configured relative to the first segment length L-120A to optimize the overall memory array performance and layout efficiency. The second segment length L-120B defines the extent over which the second wordline segment 124B provides access control for the second segment bitcell 122B and other memory cells within this segment.

The relationship between the first segment length L-120A and the second segment length L-120B may be configured in various ways to achieve different performance and layout objectives. In some cases, the first segment length L-120A may be greater than the second segment length L-120B, creating an asymmetric array configuration where the segment closer to the wordline controller 114 contains more memory cells than the remote segment. This configuration may be beneficial when the signal routing capabilities of the first fly wordline 126 can effectively serve a smaller remote segment while maximizing the memory capacity in the segment with direct wordline access.

In some cases, the first segment length L-120A may be less than the second segment length L-120B, creating a configuration where the remote segment contains more memory cells than the segment adjacent to the wordline controller 114. This arrangement may be advantageous when the first fly wordline 126 provides superior signal routing capabilities that enable reliable access to a larger number of memory cells in the remote segment. The flexibility to configure different segment length relationships enables optimization for various application requirements and manufacturing constraints.

The first segment length L-120A and the second segment length L-120B may also be configured to be substantially equal, creating a symmetric array configuration where both segments contain approximately the same number of memory cells. The symmetric configuration may provide balanced electrical characteristics and simplified design verification processes while maintaining the benefits of the segmented architecture with fly wordline signal routing. The ratio of the first segment length L-120A to the second segment length L-120B may be approximately 1:1 in the symmetric configuration, although slight variations may be accommodated based on layout constraints and electrical optimization requirements.

The segmented architecture incorporates a cut region 136 that physically and electrically separates the first array segment 120A from the second array segment 120B. The cut region 136 creates the discontinuity in the wordline structure that enables the independent signal routing approach using the first fly wordline 126. The cut region 136 may be implemented by omitting wordline material in the lower metal layer over a specific distance between the two array segments, creating the electrical isolation that prevents direct signal propagation from the first wordline segment 124A to the second wordline segment 124B while providing the physical space needed for the connection structure 134 that couples the first fly wordline 126 to the second wordline segment 124B.

The cut region 136 may be positioned at an optimal location between the array segments to balance the electrical performance and layout efficiency of the segmented memory array 120. The positioning of the cut region 136 may influence the signal routing characteristics and the effectiveness of the first fly wordline 126 in delivering wordline signals to the second array segment 120B. The width and positioning of the cut region 136 may be optimized based on the specific requirements of the connection structure 134 and the overall electrical characteristics of the segmented wordline system.

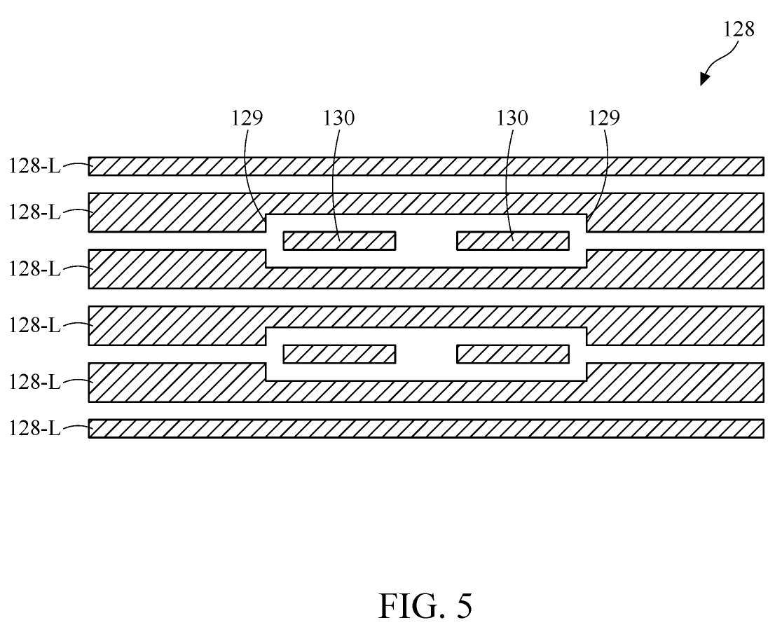

FIG. 5 illustrates a conductive interconnect layer 128 that forms part of the connection structure 134 for routing signals between different metal layers within the memory array 120. The conductive interconnect layer 128 provides a structured approach for signal distribution that enables efficient electrical connections while maintaining isolation between different signal paths. The conductive interconnect layer 128 may be positioned at an intermediate level within the metal stack, such as the third metal layer, to facilitate signal routing between the first fly wordline 126 in a higher metal layer and the second wordline segment 124B in a lower metal layer.

The conductive interconnect layer 128 includes multiple conductive lines 128-L that extend horizontally across the layer in a parallel arrangement. The conductive lines 128-L may be formed using standard metallization processes and arranged with uniform spacing between adjacent lines to create a regular pattern that facilitates predictable electrical characteristics and layout efficiency. The conductive lines 128-L may extend across portions of both the first array segment 120A and the second array segment 120B, providing a continuous conductive structure that spans the segmented memory array 120. The width and spacing of the conductive lines 128-L may be optimized based on the electrical requirements and manufacturing constraints for the particular memory device implementation.

The conductive interconnect layer 128 incorporates conductive line jogs 129 that create offset patterns within the conductive pathways. These jogs provide routing flexibility by enabling the conductive lines 128-L to change direction or position within the layer while maintaining electrical continuity.

The conductive line jogs 129 are implemented as stepped patterns that allow the conductive lines 128-L to navigate around the conductive line island 130, which forms the core element of the fly wordline interconnect structure. This jog design is particularly important in the M3 layer, where it enables the coexistence of regular signal routing through the conductive lines 128-L while accommodating the isolated conductive island 130 that serves as the vertical interconnect for the fly wordline signal path.

A conductive line island 130 is positioned within the conductive interconnect layer 128, forming an electrically isolated conductive region. The conductive line island 130 is electrically isolated from both the conductive lines 128-L and the conductive line jogs 129 within the same metal layer, creating an independent vertical interconnect element. This isolation is achieved through the M3 jog design, where the conductive line jogs 129 route around the island 130 while maintaining adequate spacing to ensure electrical isolation. The conductive line island 130 is positioned over the second array segment 120B and serves as a link in the vertical signal path, enabling the fly wordline signal to transition from the higher resistance-optimized metal layer (M5) down to the second wordline segment 124B in the M1 layer, thereby delivering the wordline signal to far-end devices with significantly reduced resistance compared to M1-only routing.

The conductive line island 130 forms a link within the vertical interconnect path that enables the wordline signal to transition from the higher metal layer of the first fly wordline 126 to the lower metal layer of the second wordline segment 124B. The conductive line island 130 may be connected to metal layers above and below the conductive interconnect layer 128 through via structures that create the vertical electrical connections, providing a controlled impedance path for the wordline signal while maintaining electrical isolation from other signal paths. The size and positioning of the conductive line island 130 may be optimized to provide adequate electrical contact area while maintaining the isolation characteristics needed for independent signal routing through the multi-layer interconnect structure.

The arrangement of the conductive lines 128-L, conductive line jogs 129, and conductive line island 130 within the conductive interconnect layer 128 creates a structured interconnect pattern that enables both regular signal routing and specialized connections for the segmented memory array architecture. The conductive lines 128-L may carry signals for other circuit functions within the memory array 120, while the conductive line island 130 provides the dedicated signal path for the fly wordline connection. The conductive line jogs 129 enable the conductive lines 128-L to accommodate the presence of the conductive line island 130 and other layout constraints while maintaining electrical continuity. The conductive interconnect layer 128 may be replicated or adapted for use in multiple intermediate metal layers within the connection structure 134 to provide additional signal routing capabilities and enhanced electrical performance for the segmented memory array system.

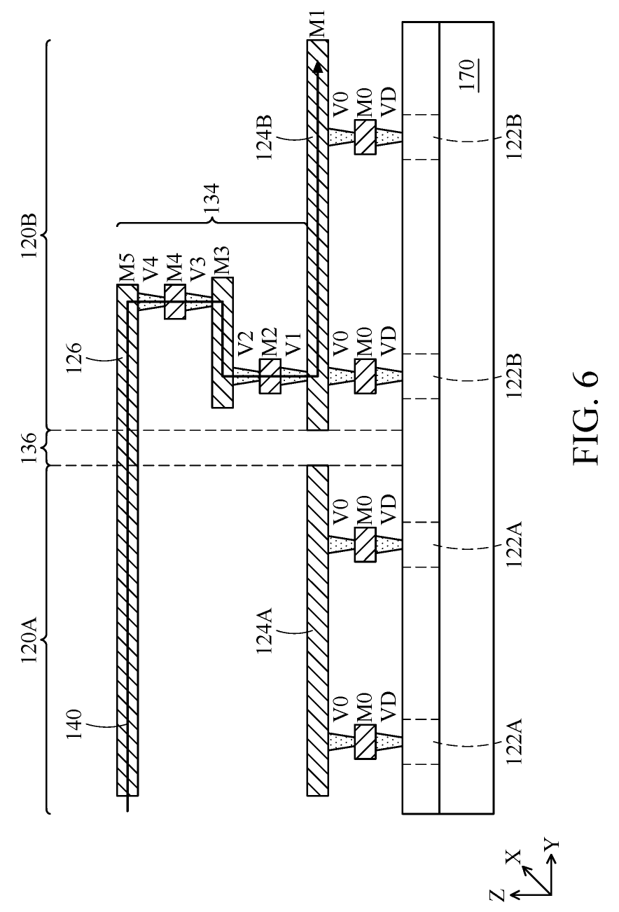

FIG. 6 illustrates a cross-sectional view of a semiconductor device structure that demonstrates the vertical interconnect architecture used to route signals between different metal layers within the segmented memory array. The cross-sectional view reveals the multi-layer metallization stack and the via connections that enable signal transmission from the first fly wordline 126 in a higher metal layer down to the second wordline segment 124B in a lower metal layer. The structure shows how the connection structure 134 utilizes multiple intermediate metal layers to create a reliable signal path that bypasses the high-resistance wordline routing, providing detailed visibility into the vertical interconnect structure that enables the segmented memory array architecture to achieve improved signal integrity and reduced electrical resistance for wordline signals.

The semiconductor device structure includes a substrate 170 that provides the foundation for the memory array components and the metallization layers. The substrate 170 may be a wafer, such as a silicon wafer, or a silicon-on-insulator (SOI) substrate. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 170 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The substrate 170 supports the various array segments and provides the mechanical foundation for the multi-layer metal interconnect structure. The substrate 170 contains the active device regions where the memory cells are fabricated.

The substrate 170 supports the first segment bitcell 122A within the first array segment 120A and the second segment bitcell 122B within the second array segment 120B, providing the physical foundation for the transistor structures that form the memory storage elements while accommodating various contact structures, local interconnect elements, doped regions, isolation structures, and other semiconductor processing features that enable the formation of the memory cell transistors and associated circuitry.

The metallization stack begins with a metal layer 0 (M0) positioned directly above the substrate 170, providing electrical connections to the active device regions within the first segment bitcell 122A and the second segment bitcell 122B. A via layer 0 (V0) provides vertical connections from M0 to the metal layer 1 (M1), which contains the wordline structures. The M1 layer includes the first wordline segment 124A extending through the first array segment 120A and the second wordline segment 124B extending through the second array segment 120B, with the cut region 136 creating electrical separation between these segments. This separation in the M1 layer is fundamental to the fly wordline architecture, preventing direct electrical connection and necessitating the innovative vertical interconnect structure through higher metal layers that will be described in the following sections.

The metallization stack continues with alternating via and metal layers that form the vertical interconnect path. Via layers V1 through V4 provide vertical connections between adjacent metal layers, while metal layers M2 through M4 serve as intermediate routing levels. The M3 layer, which corresponds to the conductive interconnect layer 128, contains the conductive line island 130 - an isolated conductive region surrounded by but electrically separated from the conductive lines 128-L and conductive line jogs 129. The M5 layer contains the first fly wordline 126, positioned at this higher level to exploit the lower sheet resistance characteristics typical of upper metallization layers. The M5 layer enables efficient signal transmission across the entire array length with significantly reduced resistance compared to M1 routing.

In some embodiments, the metal layers and vias in the interconnect structure may include one or more metal materials such as, for example, tungsten (W), copper (Cu), gold (Au), cobalt (Co), ruthenium (Ru), or combinations thereof, and may be fabricated using one or more damascene processes. The frontside metal layers are electrically and physically isolated from one another via a dielectric material (e.g., oxide-based dielectric materials or any of various other low-k dielectric materials). In some embodiments, at least one metal layer may be formed of a first material including copper at an atomic percentage greater than 80%.

The wordline signal 140 represents the electrical signal that travels through the vertical interconnect structure from the wordline controller 114 to the memory cells within the segmented array. The wordline signal 140 may originate from the wordline controller 114 and travel through the first fly wordline 126 in the M5 layer to reach the connection structure 134 positioned over the second array segment 120B. The wordline signal 140 then travels through the vertical interconnect structure, passing through the V4 layer, the M4 layer, the V3 layer, the conductive line island 130 within the M3 layer, the V2 layer, the M2 layer, the V1 layer, and finally reaching the second wordline segment 124B within the M1 layer. The wordline signal 140 demonstrates how the multi-layer interconnect approach enables signal routing from the low-resistance fly wordline to the local wordline segments while maintaining signal integrity throughout the vertical interconnect structure, enabling selective activation of memory cells within the second array segment 120B despite the electrical separation created by the cut region 136 in the lower wordline layers.

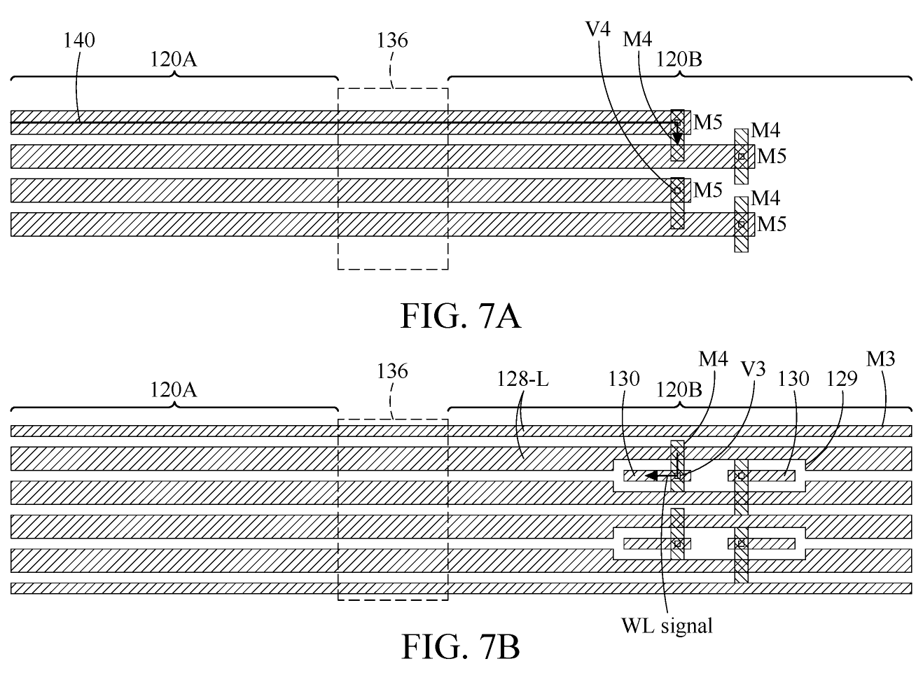

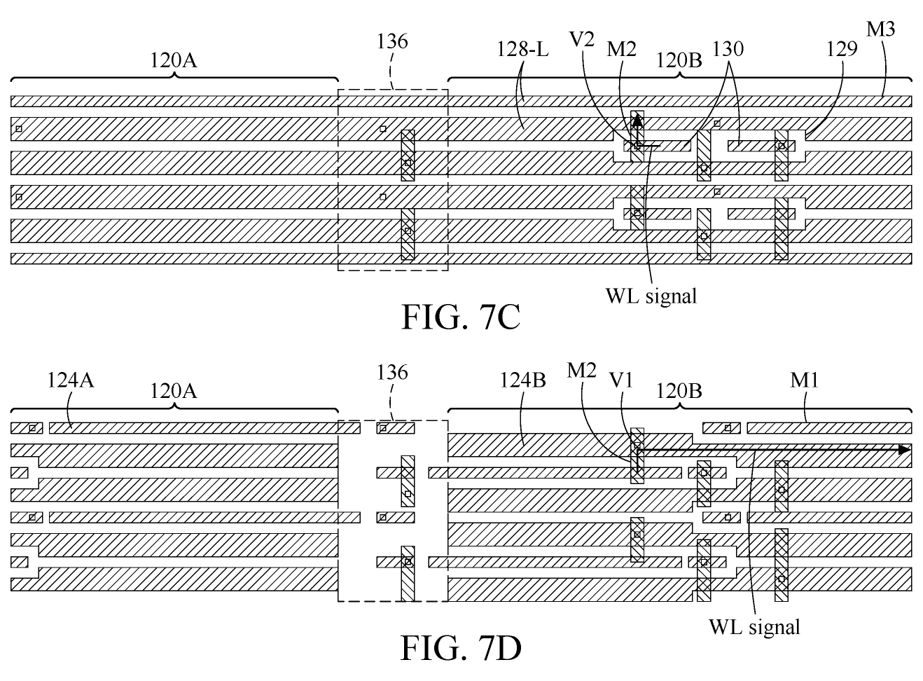

FIGS. 7A-7D illustrate circuit layouts illustrate circuit layouts showing memory regions and interconnect structures at various interconnect layers according to some embodiments. These figures demonstrate the layer-by-layer arrangement of the upper metal layers within the connection structure 134, revealing how the wordline signal 140 transitions from the first fly wordline 126 through intermediate metal layers to reach the lower wordline segments.

FIG. 7A illustrates the upper portion of the metallization stack, showing the M5 layer, the V4 layer, and the M4 layer within the first array segment 120A and the second array segment 120B. The first fly wordline 126 is formed within the M5 layer and extends horizontally across both array segments, providing a continuous conductive path that spans the segmented memory array 120. The wordline signal 140 travels along the first fly wordline 126 within the M5 layer, enabling signal transmission across the entire array structure without being affected by the cut region 136 that separates the lower wordline segments.

The V4 layer provides vertical electrical connections between the M5 layer and the M4 layer, enabling the wordline signal 140 to transition from the first fly wordline 126 to the intermediate metal layer M4 below. The M4 layer serves as an intermediate routing layer within the connection structure 134, receiving signals from the first fly wordline 126 through the V4 layer and routing the signals toward the lower metal layers.

FIG. 7B illustrates the M3 layer within the metallization stack, showing how the conductive line island 130 functions as an isolated vertical interconnect element. The M3 layer contains the conductive lines 128-L arranged in parallel with uniform spacing for regular signal routing, and the conductive line jogs 129 that create stepped offset patterns to navigate around the conductive line island 130. The conductive line island 130 is positioned over the second array segment 120B and remains electrically isolated from all surrounding conductive elements in the M3 layer. The wordline signal 140 reaches this island through the V3 layer from M4 above, demonstrating the selective vertical connection that enables the fly wordline architecture while maintaining isolation from other M3 layer signals. The M3 layer was discussed in FIG. 5 and the details are not repeated herein.

FIG. 7C illustrates the M3 layer, the V2 layer, and the M2 layer within the segmented array structure. The wordline signal 140 transitions from the conductive line island 130 within the M3 layer through the V2 layer to reach the M2 layer below. The V2 layer provides selective electrical connection to the conductive line island 130 while maintaining electrical isolation from the conductive lines 128-L and conductive line jogs 129 within the same metal layer. The V2 layer enables the wordline signal 140 to continue its downward progression through the vertical interconnect structure by creating reliable electrical contact between the M3 layer and the M2 layer. The M2 layer provides signal distribution capabilities that facilitate the transition of the wordline signal 140 from the intermediate metal layers toward the wordline segments in the lower metal layers.

FIG. 7D illustrates the transition of the wordline signal 140 from the intermediate metal layers to the wordline segments, showing the M2 layer, the V1 layer, and the M1 layer within the segmented array structure. The wordline signal 140 travels from the M2 layer through the V1 layer to reach the second wordline segment 124B within the M1 layer.

The M1 layer contains both the first wordline segment 124A and the second wordline segment 124B, which serve as the wordline structures for their respective array segments. The first wordline segment 124A extends through the first array segment 120A and may receive wordline signals directly from the wordline controller 114. The second wordline segment 124B extends through the second array segment 120B and receives wordline signals from the connection structure 134 through the vertical interconnect path that originates from the first fly wordline 126. The cut region 136 within the M1 layer creates the physical and electrical separation between the first wordline segment 124A and the second wordline segment 124B, preventing direct signal propagation between the two segments through the lower wordline layer.

A wordline signal path WL represents the electrical pathway that enables wordline signals to reach memory cells within the segmented array structure. For memory cells within the first array segment 120A, the wordline signal path WL follows a routing approach through the first wordline segment 124A within the M1 layer. For memory cells within the second array segment 120B, the wordline signal path WL utilizes the advanced routing approach that includes the first fly wordline 126, the connection structure 134, and the second wordline segment 124B.

The electrical isolation between the first wordline segment 124A and the second wordline segment 124B within the M1 layer enables independent signal control for each array segment while preventing electrical interference between the segments. The isolation is achieved through the cut region 136 that physically separates the wordline material between the two segments, creating distinct electrical domains within the same metal layer. The electrical isolation allows the first wordline segment 124A to receive signals while enabling the second wordline segment 124B to receive signals through the advanced fly wordline architecture. The isolation characteristics ensure that signal variations or electrical disturbances within one segment do not propagate to the other segment, maintaining signal integrity and reliable operation throughout the segmented memory array 120.

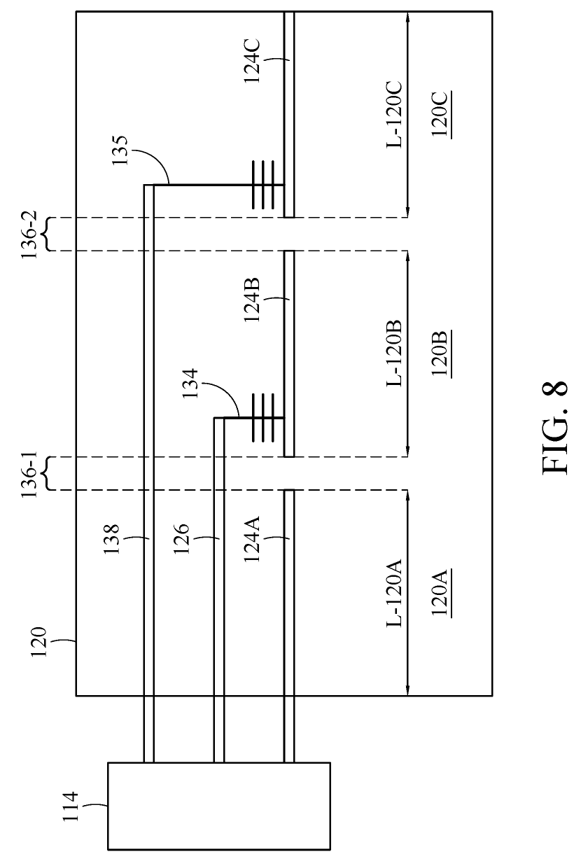

FIG. 8 illustrates a memory device configuration that extends the segmented architecture to include three array segments with dual fly wordlines operating at different metallization levels in accordance with some embodiments. This embodiment may be similar to the embodiment in FIG. 4, but demonstrates how the segmented memory array 120 may be expanded to accommodate larger memory capacities while maintaining effective signal distribution through multiple fly wordline structures. The dual fly wordline approach enables signal routing to array segments positioned at greater distances from the wordline controller 114 by utilizing different metal layers with varying electrical characteristics, providing enhanced flexibility for memory array layout optimization while addressing the signal integrity challenges associated with larger array configurations.

The memory array 120 incorporates a third array segment 120C that extends the segmented architecture beyond the two-segment configuration described previously. A third wordline section 124C extends through the third array segment 120C to provide wordline functionality for additional memory storage elements within the third array segment 120C. The third wordline section 124C may be formed in the same metal layer as the first wordline segment 124A and the second wordline segment 124B, maintaining consistency in the basic wordline structure across the expanded segmented array. The third wordline section 124C is electrically separated from the other wordline segments to enable independent signal routing through the dual fly wordline architecture, providing local access control for memory cells within the third array segment 120C and enabling selective activation during memory operations despite the electrical isolation from adjacent array segments.

The extended segmentation creates a first cut region 136-1 that separates the first array segment 120A from the second array segment 120B, and a second cut region 136-2 that separates the second array segment 120B from the third array segment 120C. These cut regions 136-1 and 136-2 are implemented by removing or omitting wordline material in the M1 layer between the array segments 120A-C, creating electrical isolation that enables the dual fly wordline architecture. In this configuration, the first fly wordline 126 in M5 may deliver signals to the second array segment 120B through an M3 isolation island structure, while the second fly wordline 138 in M7 delivers signals to the third array segment 120C through both M3 and M5 isolation island structures, demonstrating the scalability of the jog design approach.

A second fly wordline 138 provides additional signal routing capability for the extended array structure by operating in a higher metal layer than the first fly wordline 126. The second fly wordline 138 may be positioned in a metal layer 7 (M7) or other higher metallization level that exhibits even lower sheet resistance compared to the M5 layer used for the first fly wordline 126. The second fly wordline 138 extends over multiple array segments and provides an alternative signal path that enables access to array segments positioned at greater distances from the wordline controller 114, demonstrating how multiple fly wordlines operating at different metallization levels may be utilized to create a hierarchical signal distribution system that addresses the electrical resistance challenges associated with large memory arrays.

The third array segment 120C has a third section length L-120C that defines the physical extent of this array section along the wordline direction. The third section length L-120C may be independently configured relative to the first segment length L-120A and the second segment length L-120B to optimize the overall memory array performance and layout efficiency. The third section length L-120C may be determined based on factors such as the signal routing capabilities of the second fly wordline 138, the electrical characteristics of the connection structures, and the memory density requirements for this portion of the memory array 120, establishing the distance over which the third wordline section 124C extends to provide access control for memory cells within the third array segment 120C.

A second connection structure 135 provides electrical coupling between the second fly wordline 138 and the third wordline section 124C, enabling signal transfer from the low-resistance fly wordline to the local wordline segment within the third array segment 120C. The second connection structure 135 may incorporate multiple metal layers and via connections similar to the connection structure 134, creating a vertical interconnect path between the higher metal layer of the second fly wordline 138 and the lower metal layer of the third wordline section 124C.

The dual fly wordline configuration enables hierarchical signal distribution where different array segments may be accessed through fly wordlines operating at different metallization levels. The first fly wordline 126 may provide signal routing to the second array segment 120B through the connection structure 134, while the second fly wordline 138 provides signal routing to the third array segment 120C through the second connection structure 135. The hierarchical approach enables the wordline controller 114 to access memory cells throughout the extended array structure while utilizing the electrical advantages of higher metal layers for long-distance signal transmission. The dual fly wordline architecture may provide improved signal integrity and reduced electrical resistance compared to other wordline approaches, enabling reliable operation of larger memory arrays with enhanced performance characteristics while providing flexibility for optimizing the electrical characteristics and timing relationships for different array segments based on their distance from the wordline controller 114 and their specific performance requirements.

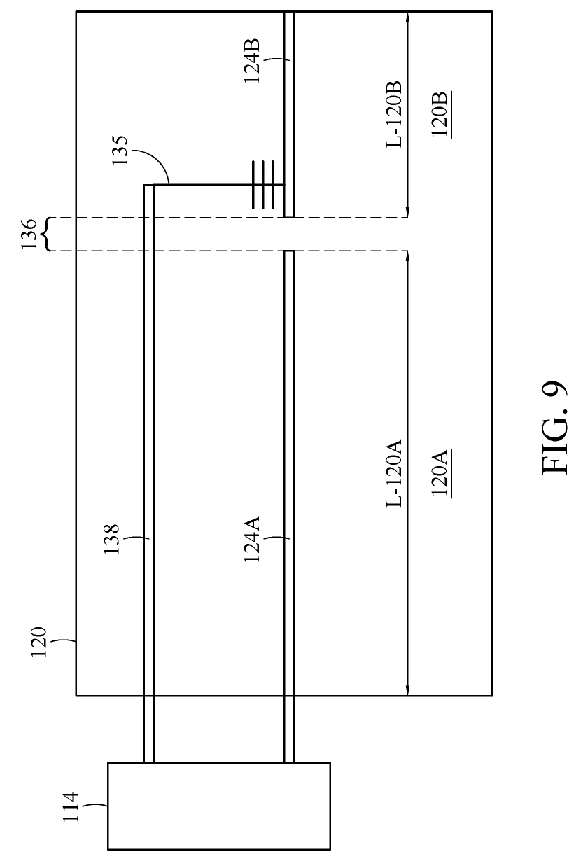

FIG. 9 illustrates a memory device configuration similar to FIG. 8 but without the first fly wordline. The configuration may provide improved electrical characteristics for memory arrays with asymmetric segment length ratios, where the first segment length L-120A may be greater than the second segment length L-120B. The second fly wordline 138 operates at a higher metal layer compared to other wordline implementations, enabling reduced electrical resistance and enhanced signal integrity for accessing remote memory segments while maintaining reliable access to memory cells positioned at varying distances from the wordline controller 114.

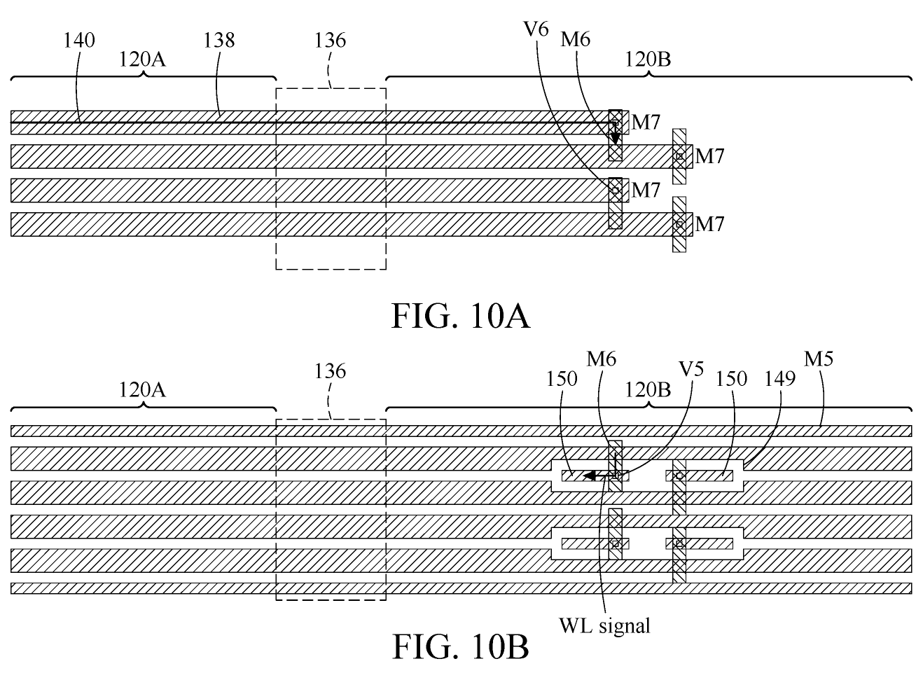

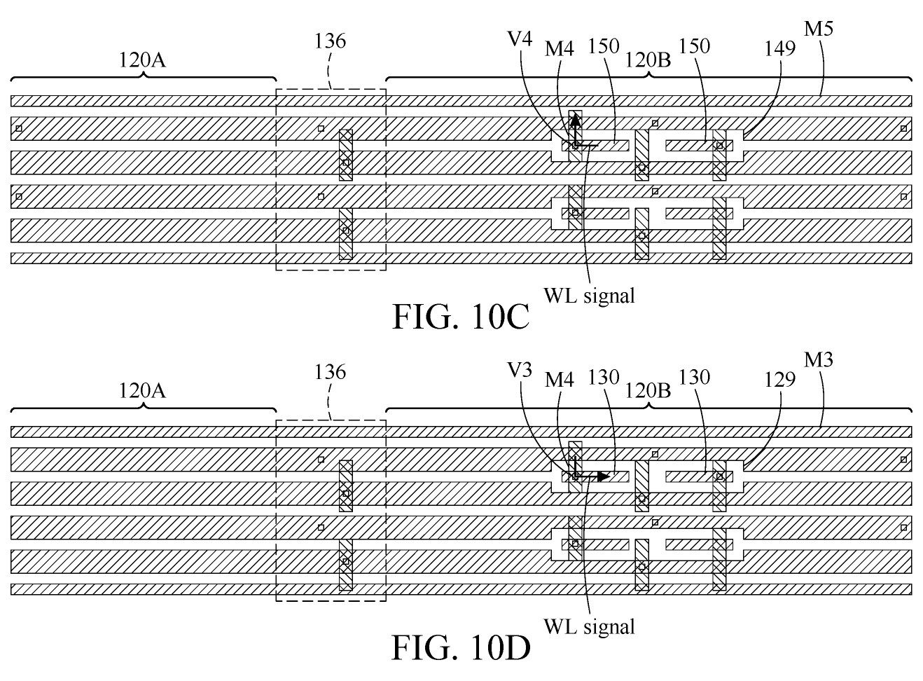

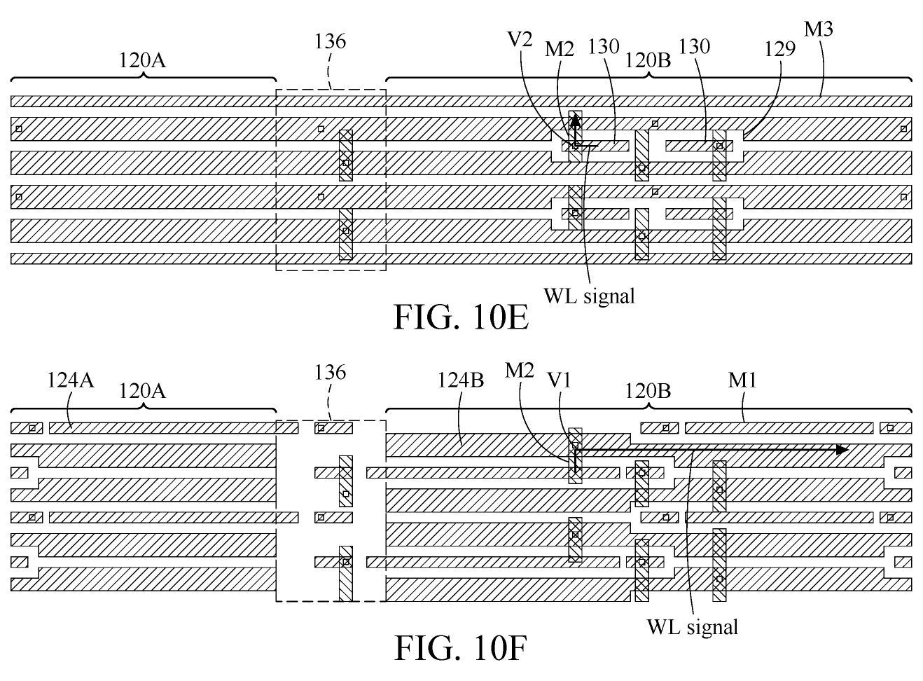

FIGS. 10A- 10F illustrate circuit layouts showing memory regions and interconnect structures in the metallization layers for the second fly wordline 138 configuration in accordance with some embodiments. These figures illustrate a layout for the FIG. 9 embodiment. These figures demonstrate the layer-by-layer arrangement of the higher metal layers within the second connection structure 135, revealing how the wordline signal 140 transitions from the second fly wordline 138 through multiple intermediate metal layers to reach the lower wordline segments. The circuit layouts provide detailed visibility into the conductive patterns and interconnect arrangements that enable reliable signal routing across the segmented memory array 120 using the advanced seventh metal layer fly wordline architecture. The figures show the spatial relationship between different metal layers and via connections that form the vertical interconnect structure for the enhanced wordline system. Details of these figures that are similar to the layout in FIGS. 7A-7D will not be repeated herein.

FIG. 10A illustrates the uppermost portion of the metallization stack, showing a metal layer 7 (M7), a via layer 6 (V6), and a metal layer 6 (M6) within the first array segment 120A and the second array segment 120B. The second fly wordline 138 is formed within the M7 layer and extends horizontally across both array segments, providing a continuous conductive path that spans the segmented memory array 120. The wordline signal 140 travels along the second fly wordline 138 within the M7 layer, enabling signal transmission across the entire array structure without being affected by the cut region 136 that separates the lower wordline segments.

The V6 layer provides vertical electrical connections between the M7 layer and the M6 layer. The M6 layer serves as the first intermediate routing layer within the second connection structure 135, receiving signals from the second fly wordline 138 through the V6 layer and routing the signals toward the lower metal layers.

FIGS. 10B through 10D illustrate the dual isolation island structure for the M7 fly wordline implementation. FIG. 10B shows the M5 layer containing conductive line island 150 with surrounding conductive line jogs 149, creating the first isolation structure in the vertical path. FIG. 10C demonstrates the signal transition through V4 to M4, while FIG. 10D shows the M3 layer with its own conductive line island 130 and jogs 129. This dual-island architecture - utilizing isolated conductive regions in both M3 and M5 - enables the wordline signal 140 from the second fly wordline 138 in M7 to reach the second wordline segment 124B in M1, demonstrating the scalability of the jog design approach for multiple fly wordline implementations. The details of the conductive line islands 130 and the conductive line jogs 129 were previously described and are not repeated herein.

FIGS. 10E and 10F illustrate the lower portion of the metallization stack for the second fly wordline 138 architecture. The details of these structures have previously been described in FIGS. 7C and 7D and are not repeated herein.

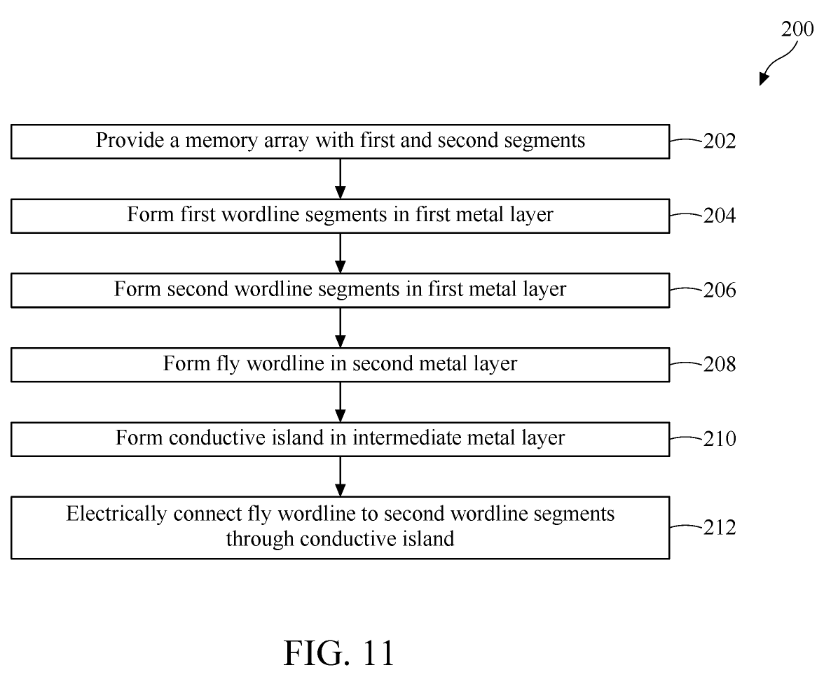

FIG. 11 illustrates a method 200 for routing signals in a memory device that addresses the electrical resistance challenges associated with segmented memory arrays. The method 200 provides a systematic approach for creating alternative signal paths that bypass the high-resistance limitations of other wordline structures while maintaining reliable access to memory cells positioned at remote locations within the memory array 120. The method 200 incorporates multiple metallization layers and vertical interconnect structures to enable efficient signal transmission across segmented array architectures, demonstrating how manufacturing processes may be coordinated to create the multi-layer interconnect structures that support advanced fly wordline architectures with improved electrical performance compared to other wordline routing approaches.

The method 200 begins with a step 202 that involves providing the memory array 120 having the first array segment 120A and the second array segment 120B. The step 202 establishes the foundational structure for the segmented memory architecture by creating discrete array sections that may be independently controlled through specialized signal routing approaches. The memory array 120 provided in the step 202 may incorporate the substrate 170 and the active device regions where the memory cells 122 are fabricated using semiconductor processing techniques. The step 202 may involve defining the physical boundaries and electrical characteristics of the first array segment 120A and the second array segment 120B to optimize the signal distribution capabilities and memory density requirements for the particular memory device implementation. The step 202 creates the structural foundation that enables the subsequent formation of segmented wordline structures and advanced interconnect systems that overcome the electrical resistance limitations of other memory array designs.

The method 200 continues with a step 204 that involves forming the first wordline segment 124A in the M1 layer to extend through the first array segment 120A. The step 204 creates the other wordline structure for the array segment positioned adjacent to the wordline controller 114, enabling direct signal routing from the control circuitry to memory cells within the first array segment 120A. The first wordline segment 124A formed in the step 204 may be fabricated using standard metallization processes that deposit and pattern conductive materials such as aluminum or copper within the M1 layer. The step 204 establishes the electrical connection pathways that enable selective activation of memory cells within the first array segment 120A during read and write operations. The first wordline segment 124A created in the step 204 provides the local access control mechanism that enables the wordline signal path WL to reach memory cells positioned within the first array segment 120A through other signal routing approaches that utilize the lower metallization layers.

The method 200 demonstrates the practical implementation of the M3 jog design innovation, where the formation of the conductive line island 130 electrically isolated from the conductive line jogs 129 enables superior wordline resistance reduction. This manufacturing approach achieves approximately 50% or greater reduction in far-end wordline resistance compared to conventional M1-only routing, while maintaining compatibility with standard CMOS fabrication processes.

A step 206 involves forming the second wordline segment 124B in the M1 layer to extend through the second array segment 120B, wherein the second wordline segment 124B may be electrically separated from the first wordline segment 124A. The step 206 creates the other wordline structure for the remote array segment while establishing the electrical isolation that enables independent signal routing through advanced interconnect approaches. The second wordline segment 124B formed in the step 206 may be fabricated using similar metallization processes as the first wordline segment 124A, maintaining consistency in the basic wordline structure across the segmented array. The electrical separation between the first wordline segment 124A and the second wordline segment 124B created in the step 206 may be achieved through the cut region 136 that physically separates the wordline material between the two segments. The step 206 establishes the local access control mechanism for the second array segment 120B while creating the electrical isolation that prevents direct signal propagation from the first wordline segment 124A through other wordline routing paths.

The method 200 includes a step 208 that involves forming the first fly wordline 126 in the M5 layer above the M1 layer, with the first fly wordline 126 extending over the first array segment 120A. The step 208 creates the low-resistance signal routing structure that enables efficient signal transmission across the segmented memory array 120 by utilizing higher metallization layers with superior electrical characteristics compared to the lower metal layers used for other wordlines. The first fly wordline 126 formed in the step 208 may be fabricated using advanced metallization processes that deposit copper or other low-resistance conductive materials within the M5 layer. The step 208 establishes the continuous conductive path that spans both the first array segment 120A and the second array segment 120B, providing an alternative signal routing approach that bypasses the electrical resistance limitations of other wordline structures. The first fly wordline 126 created in the step 208 enables the wordline signal 140 to travel across the segmented memory array 120 with reduced electrical resistance and improved signal integrity compared to other wordline routing through the M1 layer.

A step 210 involves electrically connecting the first fly wordline 126 to the second wordline segment 124B through the connection structure 134 that includes the conductive line island 130 in the M3 layer between the M1 layer and the M5 layer. The step 210 creates the vertical interconnect structure that enables signal transmission from the low-resistance fly wordline to the other wordline segment within the remote array section. The connection structure 134 formed in the step 210 may incorporate multiple via layers including the V1 layer, the V2 layer, the V3 layer, and the V4 layer that provide electrical connections between the different metallization levels. The step 210 establishes the signal routing path that enables the wordline signal 140 to transition from the first fly wordline 126 through the intermediate metal layers to reach the second wordline segment 124B despite the electrical separation created by the cut region 136. The conductive line island 130 created in the step 210 serves as an isolated conductive region within the M3 layer that enables selective signal routing while maintaining electrical separation from the conductive line jogs 129 and other conductive elements within the same metallization layer.

The method 200 may include a step 212 that involves forming the conductive line jogs 129 within the M3 layer, wherein the conductive line island 130 may be electrically isolated from the conductive line jogs 129. The step 212 creates the routing flexibility needed to accommodate multiple signal paths within the same metallization layer while maintaining the electrical isolation characteristics needed for independent signal routing. The conductive line jogs 129 formed in the step 212 may be implemented as stepped patterns that enable other conductive elements within the M3 layer to navigate around the conductive line island 130 and other layout constraints. The step 212 establishes the conductive patterns that provide other signal routing capabilities while accommodating the specialized interconnect structures needed for the advanced fly wordline architecture. The electrical isolation between the conductive line island 130 and the conductive line jogs 129 created in the step 212 enables the conductive line island 130 to function as a dedicated signal routing element for the connection structure 134 without interfering with other circuit functions within the M3 layer.

The step 210 may involve forming multiple via layers that connect the first fly wordline 126 in the M5 layer to the conductive line island 130 in the M3 layer and connect the conductive line island 130 to the second wordline segment 124B in the M1 layer. The multiple via layers created during the step 210 provide the vertical electrical connections that enable the wordline signal 140 to transition through the metallization stack while maintaining signal integrity and electrical isolation from other circuit elements. The via layers formed in the step 210 may include the V4 layer that connects the first fly wordline 126 to the M4 layer, the V3 layer that connects the M4 layer to the conductive line island 130, the V2 layer that connects the conductive line island 130 to the M2 layer, and the V1 layer that connects the M2 layer to the second wordline segment 124B. The multiple via layers enable the connection structure 134 to create a reliable signal transmission path that overcomes the electrical resistance limitations of other wordline routing while maintaining the electrical isolation characteristics needed for the segmented memory array architecture.

The method 200 enables the creation of memory devices with enhanced signal distribution capabilities that address the electrical resistance challenges associated with large memory arrays. The method 200 provides a systematic approach for implementing segmented wordline architectures with fly wordline structures that utilize higher metallization layers to achieve improved electrical performance. The method 200 demonstrates how manufacturing processes may be coordinated to create multi-layer interconnect structures that enable reliable signal transmission across segmented memory arrays while maintaining electrical isolation between different array segments. The method 200 may be adapted to support various memory array configurations including asymmetric segment lengths, multiple fly wordlines operating at different metallization levels, and extended segmentation with additional array sections that provide enhanced memory capacity and flexible layout options for advanced memory device implementations.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a memory array having a first array segment and a second array segment;
a first wordline segment extending through the first array segment;
a second wordline segment extending through the second array segment, wherein the second wordline segment is electrically separated from the first wordline segment;
a fly wordline extending over the first array segment and the second array segment in a metallization layer positioned above the first wordline segment and the second wordline segment; and
a connection structure electrically coupling the fly wordline to the second wordline segment, the connection structure comprising an isolated conductive region in an intermediate metallization layer positioned between the fly wordline and the second wordline segment.

2. The device of claim 1, wherein the fly wordline is positioned in a fifth metal layer and the first wordline segment and the second wordline segment are positioned in a first metal layer.

3. The device of claim 2, wherein the intermediate metallization layer is a third metal layer positioned between the first metal layer and the fifth metal layer.

4. The device of claim 1, wherein the intermediate metallization layer comprises conductive line jogs, and the isolated conductive region is electrically isolated from the conductive line jogs.

5. The device of claim 1, wherein the connection structure further comprises a plurality of via layers connecting the fly wordline to the isolated conductive region and connecting the isolated conductive region to the second wordline segment.

6. The device of claim 1, wherein the first array segment has a first segment length and the second array segment has a second segment length, and the first segment length is different from the second segment length.

7. The device of claim 6, wherein the first segment length is greater than the second segment length.

8. The device of claim 1, further comprising:
a first memory cell positioned in the first array segment and coupled to the first wordline segment; and
a second memory cell positioned in the second array segment and coupled to the second wordline segment.

9. The device of claim 8, wherein each of the first memory cell and the second memory cell comprises a pair of cross-coupled inverters and a pair of pass gate transistors.

10. The device of claim 1, further comprising a wordline controller positioned adjacent to the memory array and configured to provide a wordline signal to the fly wordline.

11. A device, comprising:
a memory array comprising a plurality of memory cells arranged in rows and columns;
a wordline controller positioned adjacent to the memory array;
a first wordline segment in a first metal layer extending through a first portion of the memory array, wherein the first wordline segment comprises a first material including copper at an atomic percentage greater than 80%;
a second wordline segment in the first metal layer extending through a second portion of the memory array, wherein the first wordline segment and the second wordline segment are electrically isolated from each other in the first metal layer by a cut region that physically separates wordline material between the first portion and the second portion, wherein the second wordline segment comprises a first material including copper at an atomic percentage greater than 80%;
a fly wordline in a second metal layer positioned above the first metal layer, the fly wordline extending over the first portion and the second portion in a plan view and electrically connecting to the second wordline segment; and
a vertical interconnect structure connecting the fly wordline to the second wordline segment, the vertical interconnect structure comprising at least one intermediate metal layer having an isolated conductive region that is electrically isolated from conductive line jogs within the at least one intermediate metal layer, wherein the vertical interconnect structure comprises a plurality of via layers that create electrical connections between the fly wordline, the isolated conductive region, and the second wordline segment through multiple metallization levels.

12. The device of claim 11, wherein the second metal layer is a fifth metal layer and the first metal layer is a first metal layer.

13. The device of claim 12, wherein the at least one intermediate metal layer is a third metal layer positioned between the first metal layer and the fifth metal layer.

14. The device of claim 11, wherein the isolated conductive region is electrically isolated from conductive line jogs in the at least one intermediate metal layer.

15. The device of claim 14, wherein the vertical interconnect structure further comprises a plurality of via layers connecting the fly wordline to the isolated conductive region and connecting the isolated conductive region to the second wordline segment.

16. The device of claim 15, wherein the plurality of via layers includes a first via layer connecting the fly wordline to a fourth metal layer and a second via layer connecting the isolated conductive region to a second metal layer.

17. A method, comprising:
providing a memory array having a first segment and a second segment;
forming a first wordline segment in a first metal layer to extend through the first segment;
forming a second wordline segment in the first metal layer to extend through the second segment, wherein the second wordline segment is electrically separated from the first wordline segment;
forming a fly wordline in a second metal layer above the first metal layer, the fly wordline extending over the first segment; and
electrically connecting the fly wordline to the second wordline segment through a multi-layer interconnect structure that includes a conductive island in an intermediate metal layer between the first metal layer and the second metal layer.

18. The method of claim 17, wherein the second metal layer is a fifth metal layer and the intermediate metal layer is a third metal layer.

19. The method of claim 18, wherein electrically connecting the fly wordline to the second wordline segment comprises forming a plurality of via layers connecting the fly wordline in the fifth metal layer to the conductive island in the third metal layer and connecting the conductive island to the second wordline segment in the first metal layer.

20. The method of claim 17, wherein the intermediate metal layer comprises conductive line jogs, and the conductive island is electrically isolated from the conductive line jogs.
